(19) United States
(12) Patent Application Publication
(10) Pub. No.: US 2025/0385139 A1
(43) Pub. Date: Dec. 18, 2025

(54) INSPECTION METHOD AND SYSTEM FOR INTEGRATED CIRCUIT SUBSTRATES

(71) Applicant: Onto Innovation Inc., Wilmington, MA (US)

(72) Inventors: Keith F. Best, Andover, MA (US); Syed Muhammad Burhan Ali, Stoneham, MA (US)

(21) Appl. No.: 19/131,358

(22) PCT Filed: Nov. 30, 2023
(86) PCT No.: PCT/US2023/081805

§ 371 Date: May 20, 2025

Related U.S. Application Data
(60) Provisional application No. 63/385,561, filed on Nov. 30, 2022.

(51) Int. Cl. H01L 21/66; H01L 21/67; H01L 21/68; H01L 21/683

(52) U.S. Cl. CPC H01L 22/12; H01L 21/67253; H01L 21/681; H01L 21/6838; H01L 22/14

(57) ABSTRACT

An inspection system for capturing information from substrate using one or more sensors. In some instances, a substrate can be simultaneously inspected on both sides at the same time. In other embodiments, various measurements can be performed on the overlay, features, thickness, resistance, and other parameters. These measurements can be made with various sensors such as cameras, lasers, infrared imaging, and/or x-ray sensors. The inspection system by handling the substrate carefully can avoid damage or contamination to the substrate while inspecting the substrate during stages of the process that are currently not inspected due to the downsides of conventional inspection machinery.

### CLAIM OF PRIORITY

This application claims the priority benefit to U.S. Provisional Patent Application Ser. No. 63/385,561, filed on 30 Nov. 2022, and entitled “DUAL SIDE SIMULTANEOUS INSPECTION FOR INTEGRATED CIRCUIT SUBSTRATES,” the contents of which are incorporated herein by reference in its entirety.

### TECHNICAL FIELD

The present disclosure generally relates to inspection method and inspection systems, in particular automatic inspection for substrates such as semiconductor substrates.

### BACKGROUND

Manufacturing of integrated circuit substrates has become more complex and robust. Processing can now be applied on both sides of a substrate, building separate layers on each side. However, conventional inspection techniques are not adept in handling integrated circuit substrates with structures built on both sides. In conventional inspection systems, a first side of the substrate is placed on stage or similar structure, and the second side is inspected using an inspection camera. Then, if the first side needs to be inspected, the substrate is flipped, and the same inspection process is repeated for the first side. Also, conventional inspection techniques typically cannot be used until a copper layer is etched on the layer to be inspected, because handling of the substrate without the final copper layer could lead to contamination and damage.

### SUMMARY

An inspection system for capturing information from substrate using one or more sensors. In some instances, a substrate can be simultaneously inspected on both sides at the same time. In other embodiments, various measurements can be performed on the overlay, features, thickness, resistance, and other parameters. These measurements can be made with various sensors such as cameras, lasers, infrared imaging, and/or x-ray sensors. The inspection system by handling the substrate carefully can avoid damage or contamination to the substrate while inspecting the substrate during stages of the process that are currently not inspected due to the downsides of conventional inspection machinery.

There is a need for inspection techniques that can safely and efficiently handle inspection of both sides of a substrate (e.g., an Advanced Integrated Circuit Substrate (AICS)). The inspection techniques, described herein, can hold a substrate panel while only making contact with specified keep out zones (KOZs) on the panel to not damage the processing layers on either side of the substrate panel. Also, the inspection techniques, described herein, can use at least one sensor on each side of the panel for inspection of both sides at the same time. Moreover, the inspection techniques can be used to inspect the substrate after intermediate processing steps (i.e., prior to the copper layer being etched on the layer), without a significant risk of contamination or damage to the active area of either side of the panel. This will allow the gathering of more inspection information at intermediate processing steps that was not possible using the conventional techniques described above.

In some embodiments, a method for inspecting an integrated circuit (IC) substrate is provided that includes receiving the IC substrate prior to when a copper seed layer is etched on a first layer on a first side of the IC substrate and a second layer on a second side of the IC substrate, holding the IC substrate using a holding mechanism, wherein the holding mechanism makes contact with the IC substrate on defined one or more keep out zones (KOZs), and inspecting the first side and the second side of the substrate simultaneously using a first sensor for the first side and a second sensor for the second side.

In certain embodiments, an inspection system for a dual-side inspection of integrated circuit (IC) substrate is provided that includes a holding mechanism for holding the IC substrate prior to the to a copper seed layer is etched on a first layer on a first side of the IC substrate and a second layer on a second side of the IC substrate, wherein the holding mechanism is in contact with the IC substrate on at least one keep out zones (KOZs), a first sensor to inspect the first layer on the first side of the IC substrate, and a second sensor to inspect the second layer on the second side of the IC substrate.

In some embodiments, an inspection system for dual-side inspection is provided that includes means for holding an IC substrate prior to the to a copper seed layer is etched on a first layer on a first side of the IC substrate and a second layer on a second side of the IC substrate, and means for inspecting the first layer and the second layer substantially simultaneously.

### BRIEF DESCRIPTION OF THE DRAWINGS

Various ones of the appended drawings merely illustrate example embodiments of the present disclosure and should not be considered as limiting its scope.

FIGS. 1A and 1B illustrate example portions of an IC substrate panel.

FIG. 2 illustrates example portions of a frame with an outer frame portion.

FIG. 3 illustrates example portions of a frame with an outer frame portion and an inner frame portion.

FIGS. 4A and 4B illustrate example portions of a vertically oriented inspection process.

FIGS. 5A and 5B illustrate example portions of a horizontally oriented inspection process.

FIG. 6 illustrates a flow diagram of method to perform simultaneous dual-side inspection.

FIG. 7 illustrates a block diagram of an example of a computer system used in the inspection process.

FIG. 8 illustrates example portions of an inspection system.

FIG. 9 illustrates an example layer to layer overlay through the film stack.

### DETAILED DESCRIPTION

Described herein are various inspection techniques that can safely and efficiently handle inspection of a substrate (e.g., AICS). A substrate panel can be held using only specified keep out zones (KOZs) on the panel to not damage the processing layers on either side of the substrate panel. Sensors can be placed on each side of the panel for simultaneous inspection of both sides of the substrate, such as automatic optical inspection (AOI). Notably, the inspection techniques can be adapted to inspect the substrate after intermediate processing steps (i.e., prior to the copper layer being etched on the layer), without contaminating or damaging the active area of either side of the substrate panel.

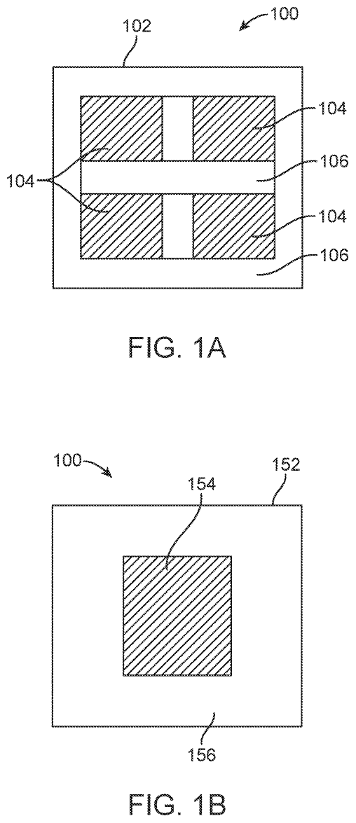

FIGS. 1A and 1B illustrate example portions of an IC substrate panel 100 (e.g., AICS). FIG. 1A illustrates a first side 102 of the IC substrate panel 100, and FIG. 1B illustrates an opposing second side 152 of the IC substrate panel 100. The first side 102 includes a plurality of active areas 104. The active areas 104 may include the area where layers of IC structures can be built. These layers are the focus of the inspection process, as described in further detail below. The first side 102 also includes keep out zones 106 (KOZs). The KOZs 106 are specified locations on each side of the substrate panel which is devoid of IC structures. The KOZs 106 can therefore be used to handle the panel during inspection. In some embodiments, the KOZs may be provided on the edges of the panel. In some embodiments, the KOZs may also be provided on inner portions of the panel. In the example shown in FIG. 1A, the KOZs 106 are provided on the edges of the panel as well as on an inner portion in a cross shape, dividing the side of the panel into four active areas 104. Other configurations can be used. For example, six or eight or other number of active areas can be provided.

As mentioned above, the IC substrate panel can have the same pattern on the opposing side. In some embodiments, as shown in FIG. 1B, the opposing second side 152 may have a different pattern of active areas KOZs. The second side 152 includes an active area 154, and KOZs 156, as shown in FIG. 1B.

For inspection, an IC substrate panel (e.g., IC substrate panel 100) may be held using the KOZs. That is, a frame may be in contact with the KOZs, but not the active areas, to hold the IC substrate panel during inspection. A frame or other holding structures can be used to hold the IC substrate panel so that substantially simultaneous inspection of both sides can be performed.

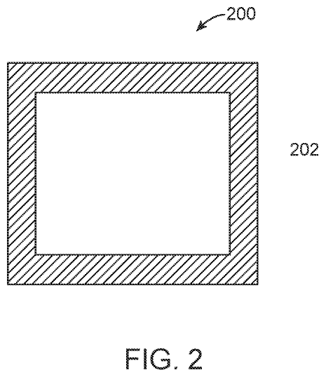

FIG. 2 illustrates example portions of a frame 200 with an outer frame portion. As shown in FIG. 2, the frame 200 includes an outer frame portion 202, which is configured to be in contact with the KOZs located on the edges of an IC substrate panel. The frame 200 may include one or more holding mechanisms such as clamps, clips, suction cups, electrostatic clamps, etc., to hold the IC substrate panel. In some embodiments, the frame 200 may include a vacuum assembly to hold the IC substrate panel. The panel can be clamped to hold from a side in a vertical direction for example leaving both sides open to inspection.

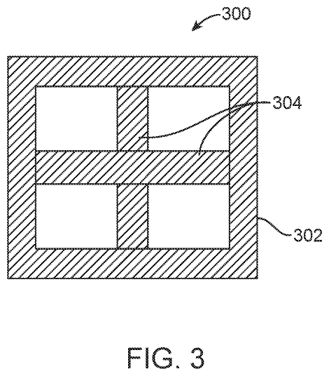

FIG. 3 illustrates example portions of a frame 300 with an outer frame portion and an inner frame portion. Here, the frame includes an outer frame portion 302, which is configured to be in contact with the KOZs located on the edges of the IC substrate panel, and an inner frame portion 304, which is configured to make contact with KOZs located an inner portion of the IC substrate panel (such as described above with reference to FIG. 1A).

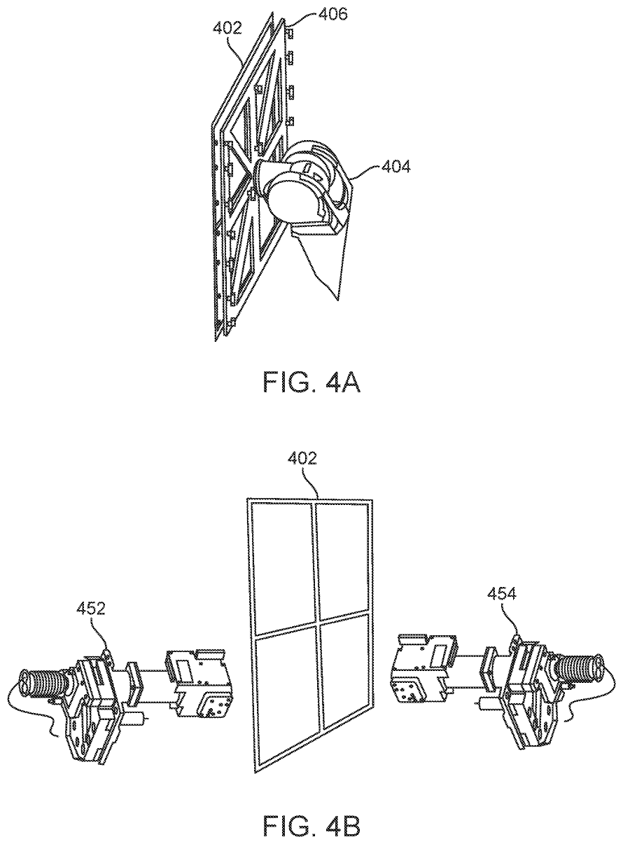

FIGS. 4A and 4B illustrate example portions of a vertically oriented inspection method. The vertically oriented inspection method is configured to inspect both sides of an IC substrate panel 402 substantially simultaneously. FIG. 4A illustrates loading of the IC substrate panel 402 for inspection. In FIG. 4A, a robotic arm 404 may be used to hold to a frame 406 that is attached IC substrate panel 402 in the KOZs of the IC substrate panel 402. The IC substrate panel 402 may then be held by the frame 406 or other holding structure in a vertical position for inspection. The robotic arm has a frame support that holds at least one KOZ areas that are at edge of the IC substrate panel to prevent from contamination on active area of both first and second sides of the panel. The frame support includes a plurality of suction cups and a clamp. The holding mechanism may use a vacuum mechanism to hold the one or more KOZ areas that are at the edge of the IC substrate panel.

FIG. 4B illustrates the substantially simultaneous inspection method of both sides of the IC substrate panel using a vertically oriented inspection system. A first sensor 452 may be positioned to face a first side of the IC substrate panel 402, and a second sensor 454 may be positioned to face a second side of the IC substrate panel 402. The first sensor 452 and the second sensor 454 may be configured to perform substantially simultaneous inspection on active areas of the respective sides of the IC substrate panel. That is, the first sensor (e.g., camera) 452 may inspect the active areas on the first side of the IC substrate panel 402 while at the same time the second sensor (e.g., camera) 454 may inspect the active areas on the second side of the IC substrate panel 402. In some embodiments, more than one camera may be provided on each side of the IC substrate panel. The sensor(s) may further include image sensors, such as CMOS or CCD sensors. In some embodiments, the sensor(s) may include an infrared sensor, a laser sensor, and/or an x-ray sensor.

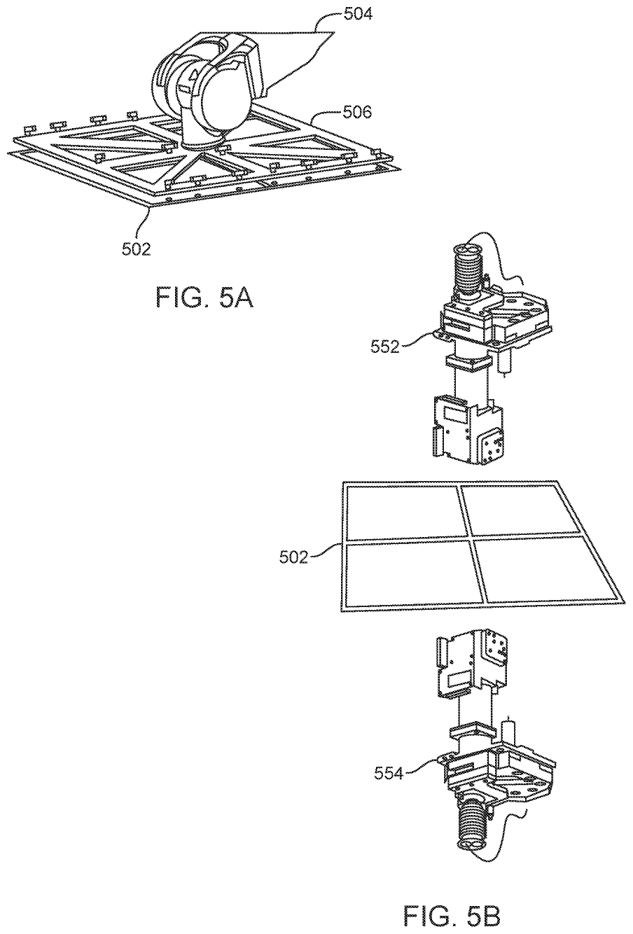

In one embodiment the simultaneous inspection can also be performed when the IC substrate panel is horizontally positioned. FIGS. 5A and 5B illustrate example portions of a horizontally oriented inspection process. The horizontally oriented inspection method is configured to inspect both sides of an IC substrate panel 502 substantially simultaneously. FIG. 5A illustrates loading of the IC substrate panel 502 for inspection. In FIG. 5A, a robotic arm 504 may be used to hold to a frame 506 that is attached IC substrate panel 502 in the KOZs of the IC substrate panel 502. The IC substrate panel 502 may then be held by the frame 406 or other holding structure in a horizontal position for inspection.

FIG. 5B illustrates the substantially simultaneous inspection method of both sides of the IC substrate panel using a horizontally oriented inspection system. A first sensor 552 may be positioned to face a first side (e.g., top side) of the IC substrate panel 502, and a second sensor 554 may be positioned to face a second side (e.g., bottom side) of the IC substrate panel 502. The first sensor 452 and the second sensor 554 may be configured to perform substantially simultaneous inspection on active areas of the respective sides. That is, the first sensor 552 may inspect the active areas on the first side of the IC substrate panel 502 while the second sensor 554 may inspect the active areas on the second side of the IC substrate panel 502. In some embodiments, more than one sensor may be provided on each side of the panel. The sensor(s) may include image sensors, such as CMOS or CCD sensors. In some embodiments, the sensor(s) may include infrared, laser, and/or x-ray sensors.

In some embodiments, the sensors (e.g., cameras) in the inspection system (including vertically oriented, horizontally oriented, or any other orientation) may be moved while the IC substrate panel is held in place to perform the inspection of the different active areas. In some embodiments, the IC substrate panel may be moved while the sensors are held in place to perform the inspection of the different active areas. In some embodiments, a combination of the sensor and IC substrate panel may be moved to perform the inspection. In certain embodiments, the substrate panel can be held vertically on one side by a clamp and be inspected by sensor(s) on either side. The substrate can be moved by electric motors, e.g., one precise electric motor in the x direction and another precise electric motor in the y direction. The electric motors can be linear motors. The cameras can also be moved by electric motors in the x, y and z axes. The holding mechanism or clamp can contain a calibration area that is used to calibrate the position of the substrate and motors to the sensors. Calibration markers on the substrate can also be used to calibrate the position within the substrate.

An IC substrate is generally a baseboard that electrically connects an IC chip and circuit board through a network of conductive copper traces and vias. As mentioned above, IC chip structures can now be built on both sides of the substrate. A typical process flow for fabricating an IC substrate includes:
1. Provide a baseboard, such as Copper Clad Laminate (CCL).
2. Machine drill holes.
3. Seed Copper (Cu) plating of holes.
4. Dry film lamination, such as a photoresist (PR) lamination.
5. PR development.
6. Cu plating.
7. PR strip.
8. Cu Etching.
9. Ajinomoto buildup film (ABF) lamination.
10. ABF curing.
11. Laser drilling.
12. De smear.
13. Seed Cu plating
14. Dry Film (PR) lamination.
15. PR development.
16. Cu plating.
17. PR strip.
18. Cu seed etching.

These steps can be applied to each side of the substrate. Steps 9-18 can be repeated for multi-layer buildup. That is, steps 9-18 can be repeated for each layer on each side of the substrate. For example, each side may have multiple lavers built (e.g., 12 layers on each side for a Dec. 2, 2012 AICS panel).

With conventional inspection techniques, the IC substrate typically could only undergo inspection after step 18 of Cu etching because of the risk of damage and contamination. For example, each layer could only be inspected after step 18 is performed for the respective layer so that the layer has a Cu etched seed layer as the top surface. However, using the inspection techniques described herein, the IC substrate can be inspected multiple times prior to a Cu etched seed layer is provided as the top surface on either of the sides (after the formation of the final redistribution layer (RDL) and before the application of the next build up laver, e.g. ABF). For example, using the inspection techniques described herein the IC substrate can be inspected after step 11 of laser drilling vias through ABF in a respective layer. As another example, the IC substrate can also be inspected after step 15 of dry film development/lithography (PR development). Thus, for each layer, at least two additional inspections can be performed to detect possible errors in the process.

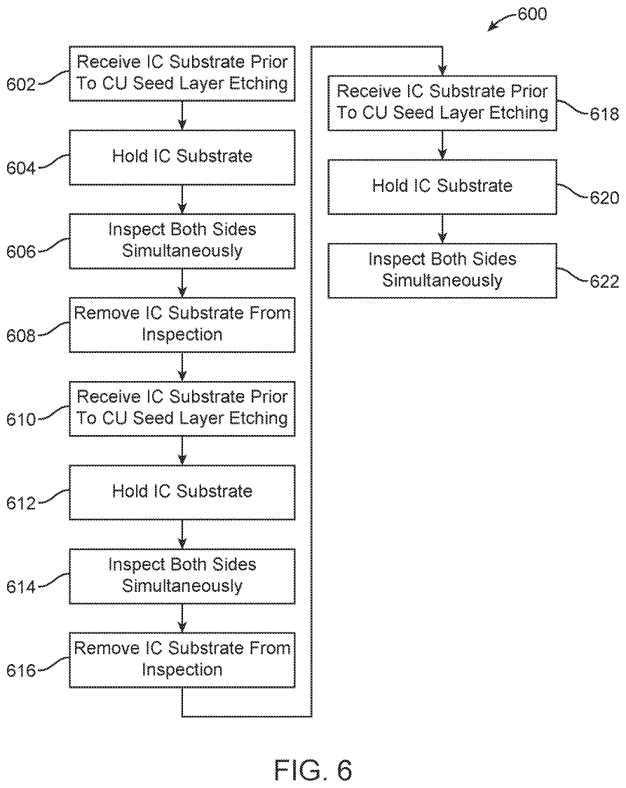

FIG. 6 illustrates a flow diagram of method 600 to perform simultaneous dual-side inspection using the inspection techniques described herein. At operation 602, an IC substrate panel may be received by an inspection system. For example, a robotic arm may pick up the IC substrate panel and move it to the inspection system. The IC substrate panel may have IC structures built on each side. The IC substrate panel may be received before the top layer on either side has a Cu seed layer etched thereon. For example, the top layers on each side may be received after laser drilling vias through ABF (e.g., step 11 of the process flow for fabricating an IC substrate described above).

At operation 604, the IC substrate panel may be held using a holding mechanism, as described above. The holding mechanism may be in contact with the IC substrate on one or more KOZs.

At operation 606, both sides of the IC substrate panel may be inspected substantially simultaneously using at least one camera for a first side of the IC substrate panel and at least one sensor(s) (e.g., a camera, an infrared sensor, a laser, and/or an x-ray) for the second side of the IC substrate panel. The sensor(s) for the first side and the sensor(s) for the second side may be placed opposed to each other in a vertical or horizontal orientation with the substrate panel in between. The laser can be a picosecond ultrasonics laser that induces an acoustic wave in the substrate that is sensed with a second laser measurement.

At operation 608, the IC substrate panel may be removed from the inspection system and may undergo further fabrication.

At operation 610, the IC substrate panel may be received by the inspection system prior to the Cu seed layer is etched on the respective layers. For example, the top layers on each side may be received after dry film development/lithography (PR development) (e.g., step 15 of the process flow for fabricating an IC substrate described above).

At operation 612, the IC substrate panel may be held using a holding mechanism, as described above. The holding mechanism may make contact with the IC substrate panel on one or more KOZs. The holding mechanism holds the substrate in a horizontal or vertical position while at least one camera inspects both sides of the substrate simultaneously.

At operation 614, both sides of the IC substrate panel may be inspected substantially simultaneously using at least one camera for the first side of the IC substrate panel and at least one camera for the second side of the IC substrate.

At operation 616, the IC substrate may be removed from the inspection system and may undergo further fabrication.

At operation 618, the IC substrate may be received by the inspection system after the Cu seed layer is etched on the respective top layers.

At operation 620, the IC substrate may be held using a holding mechanism, as described above. The holding mechanism may be in contact with the IC substrate panel on defined one or more KOZs.

At operation 622, both sides of the IC substrate may be inspected substantially simultaneously using at least one camera for the first side of the IC substrate panel and at least one camera for the second side of the IC substrate panel.

These operations can then be repeated for each layer being built on the substrate. For example, for an IC substrate panel with twelve layers on each side, this method can be performed twelve times, one for each layer. And each layer can be inspected at least three times after different manufacturing steps as described above. As compared to conventional inspection systems, which could, at best, inspect each layer only once after the Cu seed layer is etched, the inspection techniques can inspect each layer multiple times leading to more granular inspection.

The simultaneous inspection techniques, described herein, provide at least two significant advantages. The techniques can increase throughput because of the use of at least two inspection cameras and simultaneous inspection of both sides. Furthermore, the techniques can detect defects earlier in the manufacturing process because inspection can be performed prior to the copper layer being etched unlike conventional inspection techniques.

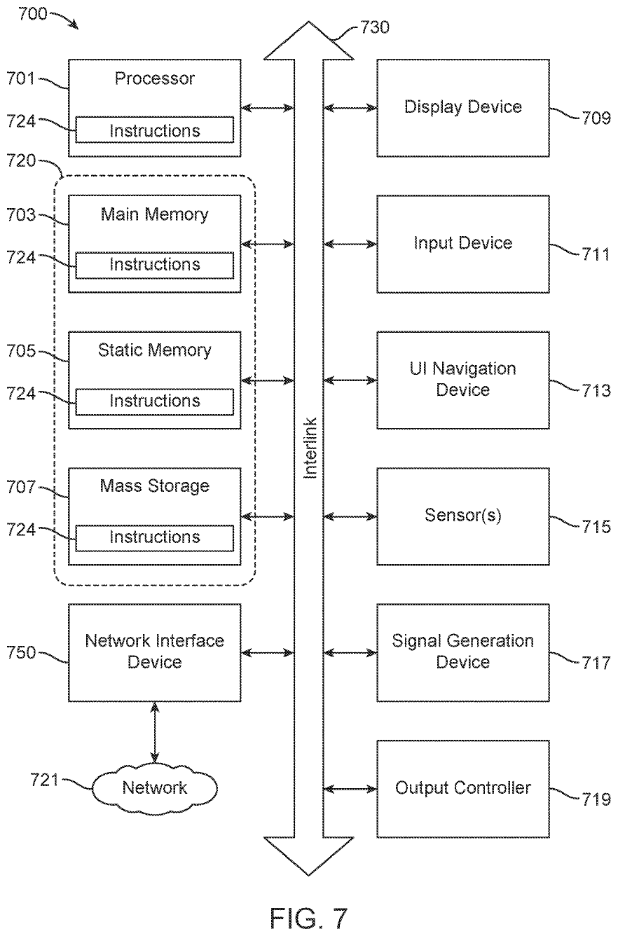

The techniques shown and described in this document can be performed using a portion or an entirety of an inspection system as described above or otherwise using a machine 700 as discussed below in relation to FIG. 7. FIG. 7 illustrates a block diagram of an example comprising a machine 700 upon which any one or more of the techniques (e.g., methodologies) discussed herein may be performed. In various examples, the machine 700 may operate as a standalone device or may be connected (e.g., networked) to other machines.

In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet device, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic or a number of components, or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware comprising the circuitry may include variably connected physical components (e.g., execution units, transistors, simple circuits, etc.) including a computer-readable medium physically modified (e.g., magnetically, electrically, such as via a change in physical state or transformation of another physical characteristic, etc.) to encode instructions of the specific operation. In connecting the physical components, the underlying electrical properties of a hardware constituent may be changed, for example, from an insulating characteristic to a conductive characteristic or vice versa. The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 700 (e.g., computer system) may include a hardware-based processor 701 (e.g., a central processing unit (CPU), a graphics processing unit (GPU), a hardware processor core, or any combination thereof), a main memory 703 and a static memory 705, some or all of which may communicate with each other via an interlink 730 (e.g., a bus). The machine 700 may further include a display device 709, an input device 711 (e.g., an alphanumeric keyboard), and a user interface (UI) navigation device 713 (e.g., a mouse). In an example, the display device 709, the input device 711, and the UI navigation device 713 may comprise at least portions of a touch screen display. The machine 700 may additionally include a storage device 720 (e.g., a drive unit), a signal generation device 717 (e.g., a speaker), a network interface device 750, and one or more sensors 715, such as a global positioning system (GPS) sensor, compass, accelerometer, or other sensor. The machine 700 may include an output controller 719, such as a serial controller or interface (e.g., a universal serial bus (USB)), a parallel controller or interface, or other wired or wireless (e.g., infrared (IR) controllers or interfaces, near field communication (NFC), etc., coupled to communicate or control one or more peripheral devices (e.g., a printer, a card reader, etc.).

The storage device 720 may include a machine readable medium on which is stored one or more sets of data structures or instructions 724 (e.g., software or firmware) embodying or utilized by any one or more of the techniques or functions described herein. The instructions 724 may also reside, completely or at least partially, within a main memory 703, within a static memory 705, within a mass storage device 707, or within the hardware-based processor 701 during execution thereof by the machine 700. In an example, one or any combination of the hardware-based processor 701, the main memory 703, the static memory 705, or the storage device 720 may constitute machine readable media.

While the machine readable medium is considered as a single medium, the term “machine readable medium” may include a single medium or multiple media (e.g., a centralized or distributed database, and/or associated caches and servers) configured to store the one or more instructions 724.

The term “machine readable medium” may include any medium that is capable of storing, encoding, or carrying instructions for execution by the machine 700 and that cause the machine 700 to perform any one or more of the techniques of the present disclosure, or that is capable of storing, encoding or carrying data structures used by or associated with such instructions. Non-limiting machine-readable medium examples may include solid-state memories, and optical and magnetic media. Accordingly, machine-readable media are not transitory propagating signals. Specific examples of massed machine readable media may include: non-volatile memory, such as semiconductor memory devices (e.g., Electrically Programmable Read-Only Memory (EPROM), Electrically Erasable Programmable Read-Only Memory (EEPROM)) and flash memory devices: magnetic or other phase-change or state-change memory circuits: magnetic disks, such as internal hard disks and removable disks: magneto-optical disks; and CD-ROM and DVD-ROM disks.

The instructions 724 may further be transmitted or received over a communications network 721 using a transmission medium via the network interface device 750 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., the Institute of Electrical and Electronics Engineers (IEEE) 802.22 family of standards known as Wi-Fi®, the IEEE 802.26 family of standards known as WiMax®, the IEEE 802.27.4 family of standards, peer-to-peer (P2P) networks, among others. In an example, the network interface device 750 may include one or more physical jacks (e.g., Ethernet, coaxial, or phone jacks) or one or more antennas to connect to the communications network 721. In an example, the network interface device 750 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 700, and includes digital or analog communications signals or other intangible medium to facilitate communication of such software.

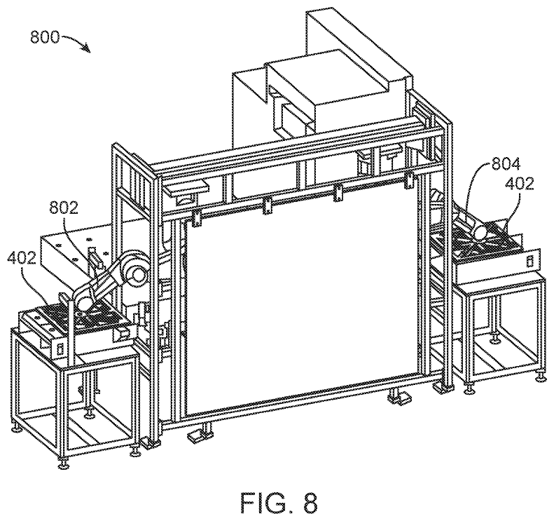

FIG. 8 illustrates an inspection system 800 that is used to take a substrate 402 (such as a panel) and inspect both sides at the same time. A robotic arm 802 can be used to grab the substrate at one end of the inspection system and bring it into an inspection area where at least two sensors positioned on either side of the substrate can be used to inspect the substrate at the same time. In certain embodiments, the panel can be passed from the robotic arm 802 to a holding mechanism that clamps, suctions, both a top side of the substrate 402. The substrate can then be moved with electric motors in x and y directions so that the sensors can scan across the substrate. When the inspection is complete, a second robotic arm 804 can take the substrate and remove it from the inspection system.

In a further detailed embodiment, it is described herein that the IC substrates typically have at least 12 layers on each side, meaning that there are 24 layers of an IC substrate panel that need to be tracked. The inspection system not only allows a user to continuously track measurement data of the layers but the data could be further sent to a processing system for choosing final calculations based on the received measurements.

In one embodiment, the system measures laser drilled holes on the surfaces of each side of the IC substrate panel during the inspection. The drilled holes are inspected by at least one sensor on each side as a holding mechanism, such as a robotic arm or a clamp, holds the panel in a horizontal or vertical position. The first and second side of the substrate can be examined simultaneously, X/Y positions of the drilled holes, with respect to the nominal locations of the structures are recorded. After recording measurements of the drilled holes using the sensor (e.g., a camera), the measurement data may be used to calculate the resistance of the structures on the panel. The formula for calculating the resistance R is ρL/A.

Information on the resistance over the build of the substrate is often tracked for metrology purposes. Machine 700, which is part of the inspection system 800 of FIG. 8 can transmit the tracked information to other servers and to semiconductor manufacturing equipment (such as a laser drilling machine) where such tracking information can be used. In another embodiment, the inspection system 800 sends the measurement data and resistance calculations to a stepper in a production line. The stepper uses the information received to calculate the stage and lens adjustments required to bring overlay back to a nominal position. The calculation is performed for both sides of the panel, and the calculated adjustments allow for an ideal positioning of the IC substrate panel.

In an example embodiment, as indicated in below table 1, resistance calculation is performed using the formula R=ρL/A.

TABLE 1

| Reference | Data (um) | Data (meters) |
|---|---|---|
| ABF thickness = | 30 | 0.00003 |
| # Layers front = | 5 | |
| # Layers back = | 5 | |
| CCL thickness = | 200 | 0.0002 |
| CD RDL = | 8 | 0.000008 |
| Plating height = | 8 | 0.000008 |
| Overlay drift = | 50 | 0.00005 |

wherein,
via nominal copper length is 0.000500 meters
nominal resistance, no overlay drift is 0.131250 ohms
overlay drift resistance is 0.144375 ohms
delta resistance is 0.013125 ohms
percentage difference is 10
copper ρ is 1.68E-08
   Resistance is calculates using the formula R=ρL/A and R is 0.0187 ohms.

In one embodiment, the system further comprises at least one sensor on each side of the IC substrate panel. These sensors are used for inspection during pattern to measure features on the substrate (such as the drilled holes or vias). Both sides, i.e., the first and second side of the substrate can be examined simultaneously, the X/Y positions of the drilled holes with respect to the nominal locations of the structures will be recorded. After recording measurements of the drilled holes using the sensors on both sides, the measurement data is further used to calculate the resistance of the RDL structures and via holes between multiple layers on the substrate panel.

Further, the captured X/Y position and RDL structures are saved in a suitable output format file on inspection system 800. These output files can then be transferred to a server or a database, which can reside within the fabrication facility or external to the fabrication facility. The inspection system 800 can also use information received from other manufacturing machines (such as a laser driller) for comparison. The inspection system can also use the RDL resistance tracker information to compare the position of holes, vias, or other features from one layer to the next. For example, the RDL resistance tracker can use the captured X/Y position features from the transferred output files of both first and second sides of the substrate panel to track center co-ordinates of the X/Y position on the front side and back side of the panel layer. The difference in pattern location between the first and second side patterns increase as the number of layers and respective substrate distortion increases. The position difference data is plotted in a heat map format to represent raw position deltas. The inspection system, such as machine 700, can also calculate resistance of the RDL structure.

The drilled holes are inspected by at least one sensor on each side. The plurality of holes and/or vias are drilled using the advanced technologies such as a laser. Simultaneous inspection of deformities across both sides of the panel gathers X, Y co-ordinate data from the laser drilled vias. This data is saved to a suitable file format and sent to a database from machine 700 of inspection system 800 to calculate a systematic lithography stepper and laser drill X/Y position errors that control the front to backside pattern registration. Such calculations can be a modelling program that provides a lithography machine with error information.

The data modelling of both first side (“A”) and second side (“B”) of the panel simultaneously can provide inter-field and intra-field systematic errors such as inter-field: Scaling X, Y, Orthogonality, Rotation: intra field: Magnification, Anamorph, Rotation.

By comparing first side (“A”) and second side (“B”) systematic errors, the difference (“A”−“B”) systematic errors provides a real time stepper and laser drill “in-line” monitor for both systems. If the “A”−“B” systematic errors go beyond a user defined limit, then the inspection system or a server will inform the user about the deformities and registration errors across all of the patterned vias.

In one embodiment, the data in the inspection system 800 may then be sent to a server for final calculations based on the received measurements allowing a user to continuously track measurement data of the layers. The server can be a computing system such as the one described in FIG. 7.

As another embodiment, the inspection system 800 using machine 700 can send the measurement data and resistance calculations to a lithography machine in a production line. The lithography machine uses the information received to calculate the stage and lens adjustments required to bring the overlay back to a nominal position. The calculation is performed for both sides of the panel, and the calculated adjustments allow for an ideal positioning of the IC substrate panel.

Further, the RDL structures, with trenches patterned in photoresist can be placed in plating equipment within the fabrication facility. The first and second sides of the panel can be simultaneously plated, and metal is deposited into the trenches. After the metal is deposited, the photoresist is removed. In one embodiment, the inspection system uses a 3D metrology sensor (such as a laser or camera system) to measure the height of the RDL structures. The sensor can be used to measure the height across different points on a panel in order to understand the distribution across the panel. The inspection system can identify deformities to create a more uniform distribution on both sides of the panel. The measurement data may be sent to server for the creation of a photograph or heat map of both sides of the panel with indications of where deformities appear. In addition to being used to create an image or a heat map, the height measurement data can be used for other inspection and measurement purposes. Differences between the height measurements on each side of the panel may be recorded and tracked on the inspection system. The inspection system can also send the information to a server for calculations. This information can be used to identify issues with the plating tool set up.

The inspection system can be used to measure Ajinomoto Build-Up Film (ABF). As described above the substrates often consist of 24 RDL layers with 12 layers on each side. There is an insulated ABF layer between each RDL layer. A 3D metrology sensor (such as a laser or camera system) can be used to measure the thickness of the ABF layer on both sides of panel. The measurement data may be sent to a server for the creation of a heat map which tracks differences in the thickness of the ABF layers on both sides of the panel.

In another embodiment, after Electrochemical Deposition (ECD) and resist and copper seed strip, the inspection system 800 can inspect deformities or defects in the copper plated RDL layer. In some embodiments, this deformity inspection can occur at the same time on both sides of the substrate. During the simultaneous first side (“A”) and second side (“B”) defect inspection by one of a sensor such as visible thickness and shape sensor (VTSS) or 3D metrology sensor can gather physical constraints such as RDL height data. This copper RDL height data from both the first side (“A”) and second side (“B”) of the substrate is saved to a suitable file format and sent to a database on the sever. The server can compare the copper plated RDL height of first side (“A”) and second side (“B”) and the difference (“A”−“B”) is represented on a heat map, histogram, etc. In certain embodiments, this can also be done on inspection system 800. This data is reported to the ECD engineer and/or the Manufacturing Execution System (MES). If the “A”−“B” systematic errors go beyond a user defined limit, the inspection system or the server will inform the user about the deformities across each copper plated RDL layer.

In yet another embodiment, the sensor is used to measure the RDL structures for the height across different points on a panel in order to understand the distribution across the panel.

The inspection system or a separate server can create of an image or a heat map of both sides of the panel with indications of where the deformities appear. The inspection system or the server can identify the deformities to create a more uniform distribution on both sides of the panel. In one embodiment, apart from being used to create an image or heat map the height measurement data can be used for other inspection and measurement purposes. Differences between the height measurements on each side of the panel may be recorded and tracked.

In some embodiments, the inspection system can record focus Z height of an inspection microscope from the panel during the inspection of the substrate. The inspection microscope is perpendicular to the substrate surface. The captured Z height data of each side of the substrate are saved in a suitable file format. This information can be sent to a separate server, which can include a database. The inspection system can perform a film thickness analysis to identify dZ values of frontside (“A”) and backside (“B”) of the panel based on difference from nominal panel thickness microscope Z height, which is defined at the first RDL layer inspection. A separate server or the inspection system can generate a heat map of the values across the substrate which provides the customer with the ABF/film thickness variation. This measurement method ensures that panel deformation does not impact the layer thickness measurement accuracy.

The inspection system can further provide data analysis such as for a film thickness histogram on a per layer, per substrate, per lot and box plots. This can be used for tracking statistical process control (SPC) key parameters such as max wedge, total indicator runout (TIR), edge vs central ABF (film thickness delta) and for lithography stepper field size and panel layout evaluation to determine the effective un-flatness of the substrate per exposure. This data can be used to determine the impact of residual un-flatness on the lithography imaging process window i.e., difference between Stepper usable depth of focus (uDOF) and residual substrate un-flatness (dZ) equals to effective Process Depth of Focus (PDOF) per stepper field. Heat maps per exposure field can be used to highlight the impact of residual un-flatness per exposure. Correlation with yield data could provide valuable insight into opportunities for ABF/film lamination and curing process optimization.

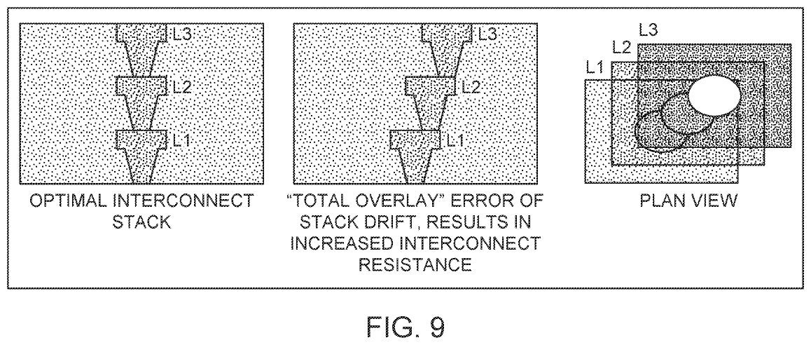

FIG. 9 illustrates overlay between three layers (L1, L2, and L3). In one part of FIG. 9 optimal interconnect stack is shown, where there is little to no overlay error between the layers. Typically, a little bit of overlay error is allowed in each layer, but over multiple layers this acceptable error can add up to an unacceptable total overly or resistance. The inspection system as described herein can detect issues and provide correction error data to a separate server or other semiconductor fabrication machines in a fabrication facility. This addition measurement and feedback loop can reduce overlay errors on a substrate. Conventionally as the number of RDL layers increases, the user is presented with a number of limitations, including achieving smaller resolution requirements and minimizing overlay errors, the latter a particular pain point facing the RDL process.

The number of RDL interconnect layers is typically between 5 and 12 layers per side connected by a plated through hole (PTH). The resulting RDL stack could contain up to 24 layers (as already described above) of layer-to-layer overlay errors. For AICS, the overlay requirements go beyond the challenging layer-to-layer specifications: they are for the entire RDL stack. The total overlay is the summation of the overlay errors for all RDL layers, with respect to the last layers on both the first and second side of the IC substrate panel. Cumulative overlay drift from individual RDL buildup layers could significantly increase overall trace length, resulting in higher interconnect resistance, parasitic effects, and poor performance for high-speed and high-frequency applications. The inspection system described herein aims to address this by monitoring of the layer-to-layer overlay performance data and calculating at each layer the errors through the film stack. This is important to avoid RDL from exceeding the design resistance specifications for a package. The system can record measurements for every RDL-to-via overlay across the entire substrate and to continuously sum the vectors, from layer to layer, as the process stack increases.

The Inspection system can use the inspection method and the data analytics to monitor, track and compensate for multi-layer overlay drift. An error signal would be generated when the cumulative overlay error exceeds a user-defined threshold. The required overlay correction offsets would then be calculated and sent to the lithography system in the fabrication facility. Without the ability to monitor the summation of overlay errors across the panel, and layer to layer, there is no way to know until final electronic test if RDL resistance meets specification, which is achieved by the current inspection system and method for inspection of integrated circuit.

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific implementations in which the invention can be practiced. These implementations are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in an aspect are still deemed to fall within the scope of that aspect. Moreover, in the following aspects, the terms “first,” “second.” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other implementations can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the aspects. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. Thus, the following aspects are hereby incorporated into the Detailed Description as examples or implementations, with each aspect standing on its own as a separate implementation, and it is contemplated that such implementations can be combined with each other in various combinations or permutations.

1. A method for inspecting an integrated circuit (IC) substrate, the method comprising:
receiving the IC substrate prior to when a copper seed layer is etched on a first layer on a first side of the IC substrate and a second layer on a second side of the IC substrate;
holding the IC substrate using a holding mechanism, wherein the holding mechanism makes contact with the IC substrate on defined one or more keep out zones (KOZs); and
inspecting the first side and the second side of the substrate simultaneously using a first sensor for the first side and a second sensor for the second side.

2. The method of claim 1, comprises inspection after laser drilling vias on the first layer and the second layer.

3. The method of claim 1, wherein the inspecting is further performed after dry film lithography on the first layer and the second layer.

4. The method of claim 1, wherein the first sensor and the second sensor are positioned on opposite sides of the IC substrate that is being held vertically, the first sensor facing the first side and the second sensor facing the second side.

5. The method of claim 1, further comprising measuring a resistance of structures on the substrate.

6. The method of claim 1, further comprising measuring an x and y axis location of features on the substrate.

7. The method of claim 1, further comprising measuring a thickness of a film on the substrate.

8. The method of claim 1, wherein the IC substrate moves during the inspecting while the first sensor and the second sensor remain substantially in place.

9. The method of claim 1, wherein the one or more KOZs are provided on an edge of the IC substrate and is devoid of active IC structures.

10. The method of claim 1, wherein the holding mechanism includes a plurality of suction cups and a clamp.

11. The method of claim 1, wherein the holding mechanism employs a vacuum mechanism for holding the IC substrate via a plurality of suction cups.

12. An inspection system for a dual-side inspection of integrated circuit (IC) substrate, the inspection system comprising:
a holding mechanism for holding the IC substrate prior to the to a copper seed layer is etched on a first layer on a first side of the IC substrate and a second layer on a second side of the IC substrate, wherein the holding mechanism is in contact with the IC substrate on at least one keep out zones (KOZs);
a first sensor to inspect the first layer on the first side of the IC substrate; and
a second sensor to inspect the second layer on the second side of the IC substrate.

13. The inspection system of claim 12, wherein the first and second sensors are configured to be positioned on opposite sides of the IC substrate, the first sensor facing the first side and the second sensor facing the second side.

14. The inspection system of claim 12, wherein the first sensor is configured to inspect the first layer after laser drilling vias on the first layer, and the second sensor is configured to inspect the second layer after laser drilling vias on the second layer.

15. The inspection system of claim 12, wherein the first sensor is configured to inspect the first layer after dry film lithography on the first layer, and the second sensor is configured to inspect the second layer after dry film lithography on the second layer.

16. An inspection system for dual-side inspection, the inspection system comprising:
means for holding an IC substrate prior to the to a copper seed layer is etched on a first layer on a first side of the IC substrate and a second layer on a second side of the IC substrate; and
means for inspecting the first layer and the second layer substantially simultaneously.
